(19) United States
(12) Patent Application Publication
(10) Pub. No.: US 2019/0072998 A1
(43) Pub. Date: Mar. 7, 2019

(54) SLIDING DEVICE FOR MOBILE DEVICE

(71) Applicant: Deok Ki HWANG, Seoul (KR)

(72) Inventor: Deok Ki HWANG, Seoul (KR)

(21) Appl. No.: 15/773,968

(22) PCT Filed: Jan. 31, 2018
(86) PCT No.: PCT/KR2018/001334

§ 371 Date: May 4, 2018

(30) Foreign Application Priority Data
Mar. 7, 2017 (KR) 10-2017-0029070

(51) Int. Cl. G06F 1/16; H05K 7/14; H05K 5/03

(52) U.S. Cl. CPC G06F 1/1628; H05K 5/03; H05K 7/1418

(57) ABSTRACT

Disclosed herein is a sliding device for a mobile device. The sliding device is provided on a folding case, and reciprocates the mobile device into and from the folding case. The sliding device includes: a stationary plate installed on the inside of the folding case; a movable plate configured such that the mobile device is fastened thereto and it reciprocates along the stationary plate in a first direction; and guide members bent in opposite directions so that both ends of the movable plate in a second direction perpendicular to the first direction are fitted thereinto. A plurality of fastening grooves is formed on the top surface of the stationary plate to be spaced apart from each other in the first direction. A protrusion configured to be selectively inserted into the plurality of fastening grooves is formed on the bottom surface of the movable plate.

### TECHNICAL FIELD

The present invention relates to a sliding device, and more specifically to a sliding device provided in a case configured to protect a mobile device.

### BACKGROUND ART

Generally, mobile devices, such as smartphones, mobile phones, etc., are commercialized in various sizes. Cameras are provided at respective specific locations of the back surfaces of the mobile devices having various sizes. Accordingly, users can take photos or moving images via the mobile devices.

Furthermore, cases configured to prevent the occurrence of accidents, such as a scratch, damage, etc., and to protect mobile devices are mounted and used on mobile devices. In this case, through holes may be formed in the cases in order to enable the cameras of the mobile devices to perform photographing.

Furthermore, commercialized cases include various types of cases: cases designed to protect only the frames of mobile devices; and folding cases designed in wallet forms and configured to protect overall mobile devices including liquid crystal displays. These cases are manufactured in various sizes in order to enable mobile devices to be mounted thereon.

In other words, the cases and the through holes provided in the cases are designed to fit various types of respective mobile devices, and thus a problem arises in that it is difficult to use a single case for various types of mobile devices.

Meanwhile, the background art of the present invention is disclosed in Korean Patent No. 10-1606483.

### DISCLOSURE

### Technical Problem

The present invention has been conceived to overcome the above-described problems, and an object of the present invention is to provide a sliding device for a mobile device, which enables various types of mobile devices to be mounted on a single case and which also enables the cameras of various types of mobile devices to perform photographing.

### Technical Solution

According to an aspect of the present invention, there is provided a sliding device for a mobile device, which is provided on a folding case configured to protect the mobile device and reciprocates the mobile device into and from the case, the sliding device including: a stationary plate installed on the inside of the folding case; a movable plate configured such that the mobile device is fastened thereto and it reciprocates along the stationary plate in a first direction; and guide members bent in opposite directions so that both ends of the movable plate in a second direction perpendicular to the first direction are fitted thereinto, and configured to guide the movable plate through movement in the first direction; wherein a plurality of fastening grooves is formed on the top surface of the stationary plate to be spaced apart from each other in the first direction; and wherein a protrusion configured to be selectively inserted into the plurality of fastening grooves is formed on the bottom surface of the movable plate.

According to another aspect of the present invention, there is provided a sliding device for a mobile device, which is provided on a folding case configured to protect the mobile device and reciprocates the mobile device into and from the case, the sliding device including: a stationary plate installed on the inside of the folding case; a movable plate configured such that the mobile device is fastened thereto and it reciprocates along the stationary plate in a first direction; and guide members bent in opposite directions so that both ends of the movable plate in a second direction perpendicular to the first direction are fitted thereinto, and configured to guide the movable plate through movement in the first direction; wherein the stationary plate include an outer plane, and an inner plane depressed below the outer plane, famed long in the first direction, and configured such that a plurality of fastening grooves is formed thereon to be spaced apart from each other in the first direction; wherein a protrusion configured to be selectively inserted into the plurality of fastening grooves is formed on the bottom surface of the movable plate; wherein an inclined surface inclined upward toward the inner plane is foiled at an end of the outer plane to guide the protrusion to the inner plane; and wherein the distance between the bottom surface of the outer plane and the lowest point of the inclined surface is shorter than the distance between the bottom surface of the outer plane and the lowest point of each of the fastening grooves.

### Advantageous Effects

In accordance with the sliding device for a mobile device according to the present invention, a mobile device can be slid along a folding case, and thus the cameras of various types of mobile devices can perform photographing on a single folding case.

Furthermore, the movable plate can be easily mounted into and separated from the stationary plate.

Furthermore, the sliding of a mobile device can be stopped at a point desired by a user.

Moreover, a mobile device can be prevented from being separated from a folding case.

### DESCRIPTION OF DRAWINGS

FIG. 1 is a perspective view showing the state in which a mobile device has been mounted on a folding case according to an embodiment of the present invention;

FIG. 2 is a view showing the state in which a sliding device for a mobile device has been mounted on the folding case shown in FIG. 1;

FIG. 3 is a perspective view showing the sliding device for a mobile device shown in FIG. 2;

FIG. 4 is an exploded perspective view of the sliding device for a mobile device shown in FIG. 3;

FIG. 5 is a sectional view taken along line A-A of FIG. 4;

FIG. 6 is a sectional view taken along line B-B of FIG. 4;

FIG. 7 is a view illustrating a protrusion according to another embodiment of the present invention;

FIG. 8 is a perspective view showing a sliding device for a mobile device according to still another embodiment of the present invention;

FIG. 9 is a sectional view taken along line C-C of FIG. 8; and

FIG. 10 is a sectional view taken along line D-D of FIG. 4.

### MODE FOR INVENTION

Some embodiments of the present invention will be described in detail below via exemplary drawings. It should be noted that when reference symbols are assigned to components of the drawings, the same reference symbols will be assigned to the same components as much as possible even when the components are illustrated in different drawings.

Furthermore, in the description of the embodiments of the present invention, if it is determined that a detailed description of a related well-known configuration or function obstructs the understanding of an embodiment of the present invention, the detailed description will be omitted.

Furthermore, in the description of the components of the embodiments of the present invention, the terms “first,” “second,” “A,” “B,” “(a),” “(b),” etc. may be used. Each of these terms is used merely to distinguish one component from another component, but the essence, sequential position, or the like of the corresponding component is not limited by the term.

Referring to the drawings, a sliding device for a mobile device according to embodiments of the present invention will be described in detail below.

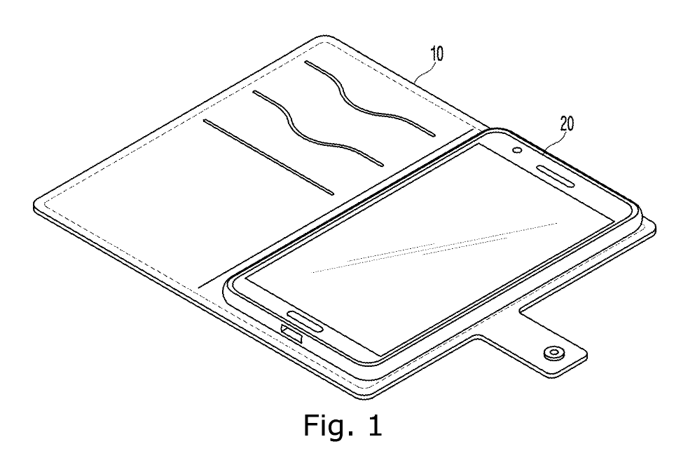

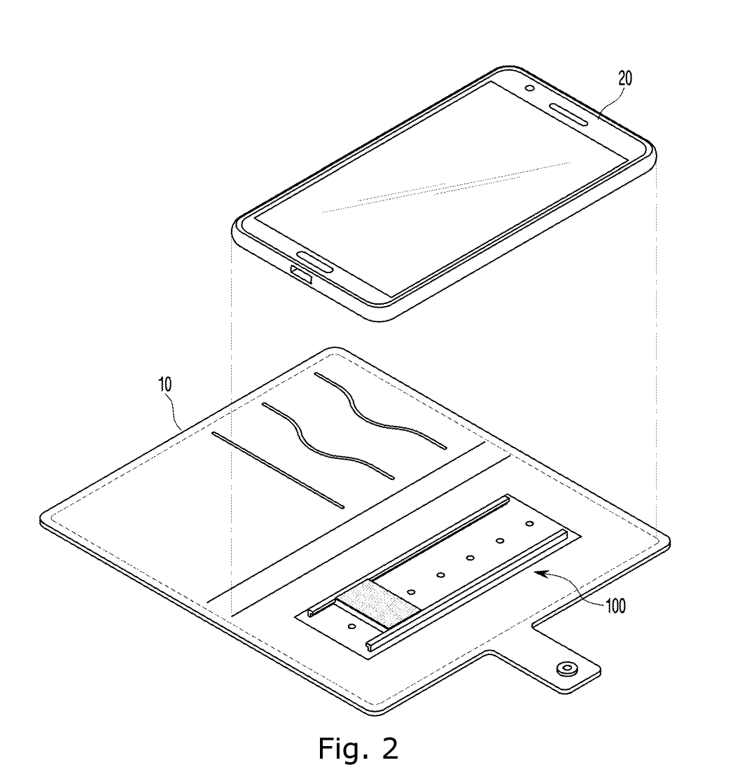

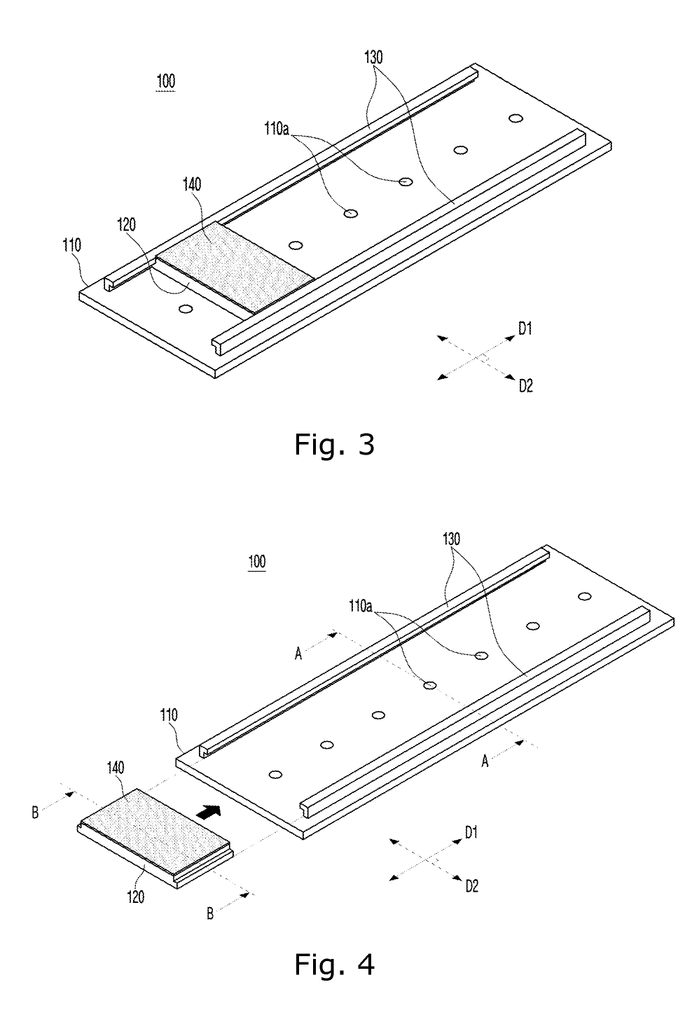

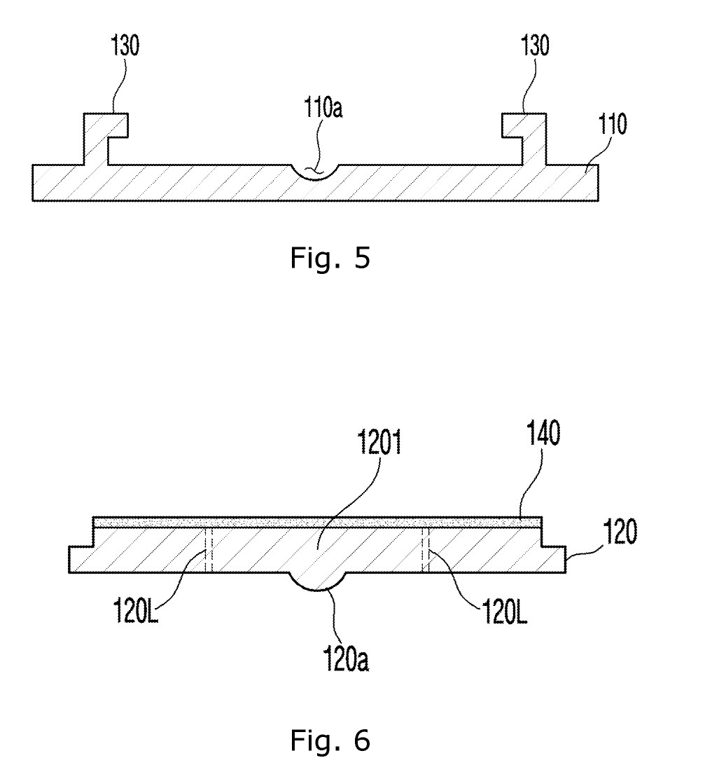

Referring to FIG. 1, there is shown a perspective view showing the state in which a mobile device has been mounted on a folding case according to an embodiment of the present invention, FIG. 2 is a view showing the state in which a sliding device for a mobile device has been mounted on the folding case shown in FIG. 1, FIG. 3 is a perspective view showing the sliding device for a mobile device shown in FIG. 2, FIG. 4 is an exploded perspective view of the sliding device for a mobile device shown in FIG. 3, FIG. 5 is a sectional view taken along line A-A of FIG. 4, and FIG. 6 is a sectional view taken along line B-B of FIG. 4.

Referring to FIGS. 1 to 6, a sliding device 100 for a mobile device according to an embodiment of the present invention may be installed on a case 10 configured to protect a mobile device 20, such as a smartphone or the like, from a scratch, damage, contaminants, etc.

For example, the sliding device 100 for a mobile device may be provided on a wallet-type folding case 10, and may reciprocate the mobile device 20 into/from the folding case 10.

In other words, the sliding device 100 for a mobile device may slide the mobile device 20 along the folding case 10, and may enable mobile devices having various forms to be mounted on the single folding case 10 and also enable the cameras of mobile devices to perform photographing.

The sliding device 100 for a mobile device may include a stationary plate 110 and a movable plate 120.

The stationary plate 110 may be installed inside the folding case 10.

For example, the stationary plate 110 is installed on the folding case 10 in such a manner that the edges of the stationary plate 110 are fastened to the inside of the leather of the folding case 10.

Furthermore, the movable plate 120 is installed into the stationary plate 110 so that the movable plate 120 is movable along the stationary plate 110 in a first direction D1. The mobile device 20 may be fastened to the movable plate 120.

Accordingly, in the state in which the folding case 10 has been closed, part of the mobile device 20 may be exposed from the folding case 10 to the outside by the movement of the movable plate 120.

The sliding device 100 for a mobile device may further include a pair of guide members 130.

The pair of guide members 130 are spaced apart from each other, and may be bent in opposite directions.

Both ends of the movable plate 120 in a second direction D2 perpendicular to the first direction D1 are fitted into the guide members 130. When the movable plate 120 is moved, the guide members 130 may guide the movable plate 120 through its movement.

Meanwhile, a plurality of fastening grooves 110a is formed through the top surface of the stationary plate 110 to be spaced apart from each other in the first direction D1.

Furthermore, a protrusion 120a configured to be selectively inserted into the plurality of fastening grooves 110a may be formed on the bottom surface of the movable plate 120.

Accordingly, the protrusion 120a may be selectively inserted and seated onto the plurality of fastening grooves 110a while reciprocating in the first direction D1.

Furthermore, the protrusion 120a may have a hemispheric shape, and the plurality of fastening grooves 110a may have a shape corresponding to that of the protrusion 120a having the hemispheric shape.

When the protrusion 120a is inserted into any one of the plurality of fastening grooves 110a, the protrusion 120a may be separated from any one of the plurality of fastening grooves 110a only when external force is applied, and thus the mobile device 20 may be fastened after being exposed from the folding case 10.

Meanwhile, cut portions 120L may be provided in the movable plate 120 on both sides of the protrusion 120a.

The first portion 1201 of the movable plate 120 in which the protrusion 120a is formed may be elastically deformed by the cut portions 120L, and thus the surfaces of the protrusion 120a and the plurality of fastening grooves 110a may be prevented from being deformed due to the friction therebetween when the protrusion 120a is inserted into or separated from the plurality of fastening groove 110a.

Furthermore, an adhesive portion 140 made of an elastic material may be provided on the top surface of the movable plate 120.

The adhesive portion 140 is deformed when the first portion 1201 is deformed, and thus the first portion 1201 may be elastically deformed desirably after the mobile device 20 has been installed on the movable plate 120.

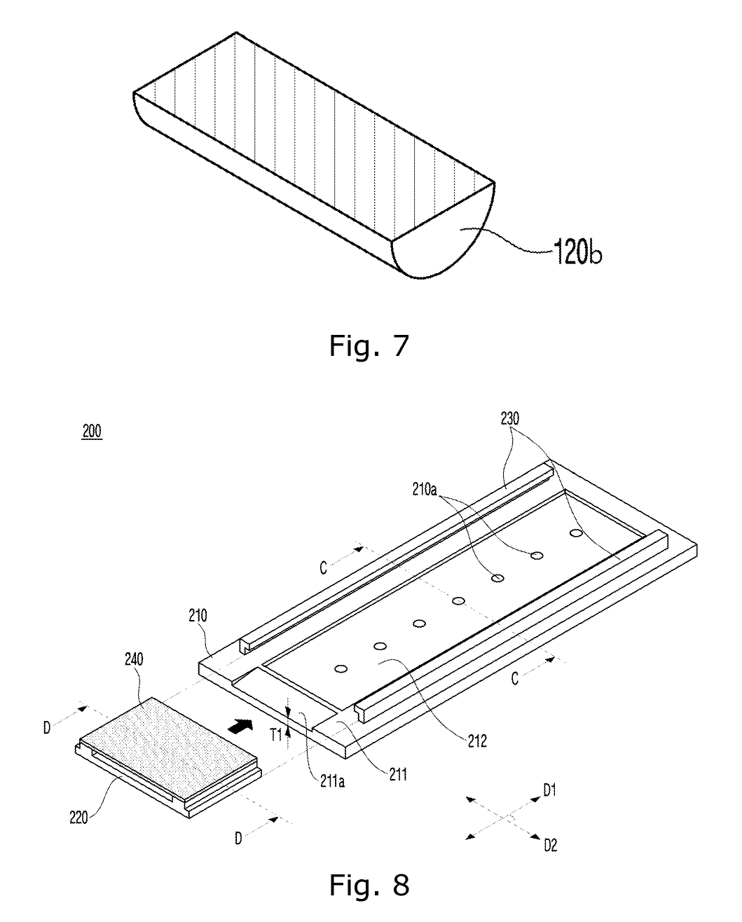

FIG. 7 is a view illustrating a protrusion according to another embodiment of the present invention.

Referring to FIG. 7, the protrusion 120b may be formed long in the second direction D2, and may have a convex curved surface in the first direction D1. Accordingly, each of the plurality of fastening grooves 110a may have a shape corresponding to that of the protrusion 120b.

When the protrusion 120b is separated from the plurality of fastening grooves 110a, a load applied to the protrusion 120b may be spread, and thus the surfaces of the protrusion 120b and the plurality of fastening grooves 110a may be prevented from being deformed due to the friction therebetween.

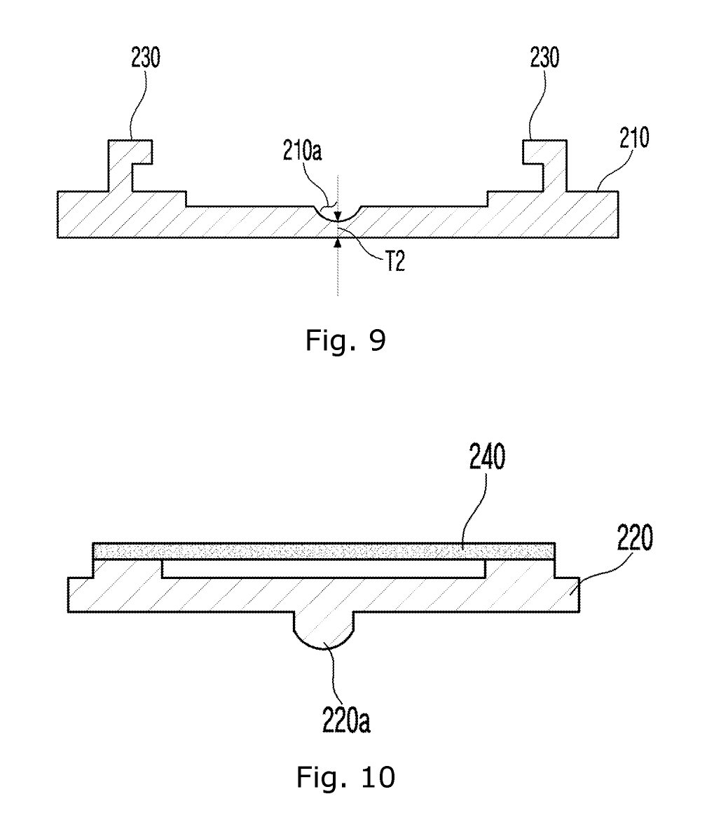

FIG. 8 is a perspective view showing a sliding device for a mobile device according to still another embodiment of the present invention, FIG. 9 is a sectional view taken along line C-C of FIG. 8, and FIG. 10 is a sectional view taken along line D-D of FIG. 4.

Referring to FIGS. 8 to 10, a sliding device 200 for a mobile device according to still another embodiment of the present invention may include a stationary plate 210 and a movable plate 220.

Furthermore, the stationary plate 210 may include an outer plane 211 and an inner plane 212.

The inner plane 212 is dispose inside the outer plane 211.

The inner plane 212 may be depressed below the outer plane 211, and may be formed long in the first direction D1.

Furthermore, the plurality of fastening grooves 210a may be formed on the inner plane 212.

The movable plate 220 may include a first portion configured such that a protrusion 220a is formed on the bottom surface thereof and a second portion configured to be fitted into guide members 230 fastened to the stationary plate 210.

The movement of the protrusion 220a out of the inner plane 212 is limited by the outer plane 211. Accordingly, even when the elasticity of the first portion on which the protrusion 220a is formed is low, the separation of the movable plate 220 from the stationary plate 210 may be prevented, and thus the mobile device 20 may be prevented from being separated from the folding case 10.

Meanwhile, an inclined surface 211a inclined upward toward the inner plane 212 may be formed at an end of the outer plane 211.

Furthermore, the distance T1 between the bottom surface of the outer plane 211 and the lowest point of the inclined surface 211a may be shorter than the distance T2 between the bottom surface of the outer plane 211 and the lowest point of each of the fastening grooves 210a.

The inclined surface 211a guides the protrusion 220a to the inner plane 212, and thus the movable plate 220 may be easily mounted into the stationary plate 210.

Although all the components constituting each of the embodiments of the present invention are described as being combined into one or as being combined into one and then operated above, the present invention is not limited to the embodiments. In other words, within the scope of the objects of the present invention, all the components may be selectively combined into one or more and then operated.

Furthermore, unless defined otherwise, all the above-described terms, including technical or scientific terms, have the same meanings as commonly understood by those skilled in the art to which the present invention pertains. The commonly used terms, such as those defined in dictionaries, should be interpreted as having meanings consistent with their meanings in the context of relevant art, and should not be interpreted in an idealized or overly formal sense unless expressly so defined herein.

The above description is intended merely to illustrate the technical spirit of the present invention. It will be apparent to those having ordinary knowledge in the art to which the present invention pertains that various modifications and alterations are possible without departing from the essential features of the present invention. Accordingly, the embodiments disclosed herein are not intended to limit the technical spirit of the present invention, but are intended to illustrate the technical spirit of the present invention. The scope of the technical spirit of the present invention is not limited by these embodiments and the accompanying drawings. The range of protection of the present invention should be defined based on the attached claims, and all technical spirits falling within a range equivalent to the claims should be construed as being included in the range of rights of the present invention.

What is claimed is:

1. A sliding device for a mobile device, which is provided on a folding case configured to protect the mobile device and reciprocates the mobile device into and from the case, the sliding device comprising:
a stationary plate installed on an inside of the folding case;
a movable plate configured such that the mobile device is fastened thereto and it reciprocates along the stationary plate in a first direction; and
guide members bent in opposite directions so that both ends of the movable plate in a second direction perpendicular to the first direction are fitted thereinto, and configured to guide the movable plate through movement in the first direction;
wherein a plurality of fastening grooves is formed on a top surface of the stationary plate to be spaced apart from each other in the first direction; and
wherein a protrusion configured to be selectively inserted into the plurality of fastening grooves is formed on a bottom surface of the movable plate.

2. A sliding device for a mobile device, which is provided on a folding case configured to protect the mobile device and reciprocates the mobile device into and from the case, the sliding device comprising:
a stationary plate installed on an inside of the folding case;
a movable plate configured such that the mobile device is fastened thereto and it reciprocates along the stationary plate in a first direction; and
guide members bent in opposite directions so that both ends of the movable plate in a second direction perpendicular to the first direction are fitted thereinto, and configured to guide the movable plate through movement in the first direction;
wherein the stationary plate comprises:
an outer plane; and
an inner plane depressed below the outer plane, formed long in the first direction, and configured such that a plurality of fastening grooves is formed thereon to be spaced apart from each other in the first direction;
wherein a protrusion configured to be selectively inserted into the plurality of fastening grooves is formed on a bottom surface of the movable plate;
wherein an inclined surface inclined upward toward the inner plane is formed at an end of the outer plane to guide the protrusion to the inner plane; and
wherein a distance between a bottom surface of the outer plane and a lowest point of the inclined surface is shorter than a distance between the bottom surface of the outer plane and a lowest point of each of the fastening grooves.
